(19) United States
(12) Patent Application Publication
(10) Pub. No.: US 2004/0149926 A1
(43) Pub. Date: Aug. 5, 2004

(54) Emittance measuring device for ion beams

(76) Inventors: Kenneth H. Purser, Lexington, MA (US); Carl J. Russo, Burlington, CT (US); Norman L. Turner, Vero Beach, FL (US)

Correspondence Address: Henry C. Nields, Nields & Lemack, Suite 7, 176 E. Main Street, Westboro, MA, 01581, US

(21) Appl. No.: 10/733,779

(22) Filed: Dec. 11, 2003

Related U.S. Application Data
(60) Provisional application No. 60/432,433, filed on Dec. 11, 2002.

(51) Int. Cl. H01J 37/244

(52) U.S. Cl. 250/397; 324/71.3

(57) ABSTRACT

Methods and apparatus are disclosed for rapidly providing for a large number of closely spaced points within an area at right angle to the central trajectory of an ion beam data concerning intensity variations, emittance variations and angular variations of elementary beamlets with respect to the central beam trajectory. The technology is particular applicable to the application and control of ribbon beams used for semiconductor implantation.

### CROSS REFERENCE AND RELATED APPLICATIONS

This Application claims priority of U.S. provisional patent application Serial No. 60/432,433 filed Dec. 11, 2002 entitled “Emittance Measuring Device for Ion Beams”, the disclosure of which is incorporated herein by reference in its entirety.

### FIELD OF INVENTION

Transducer for providing angle and beam intensity data required during semiconductor implantation and doping to provide input for corrector algorithms useful for manual or automated set-up of focusing and correction elements.

### BACKGROUND TO THE INVENTION

The process of ion implantation is useful in semiconductor manufacturing as it makes possible the modification of the electrical properties of well-defined regions of a silicon wafer by selectively introducing impurity atoms, one by one. These incoming atoms penetrate the surface layers and come to rest at a specified depth below the surface. Implantation makes possible the creation of three-dimensional electrical circuits and micro-transistors with great precision and reproducibility.

The characteristics that make implantation such a useful processing procedure are threefold: First, the concentration of introduced dopant atoms can be accurately measured by straight-forward determination of the incoming electrical charge that has been delivered when the implanted ions impact the wafer. Secondly, the regions of the silicon wafer where the dopant atoms are inserted can be precisely defined by photo resist masks that make possible precise dopant patterning at ambient temperatures. Finally, the depth at which the dopant atoms come to rest can be adjusted by varying the incoming ion energy making possible fabrication of layered structures. Typically, implantation takes place within a vacuum chamber where a robot loads and unloads wafers onto an electrostatic chuck or a rotating disc that is moved in a manner that passes the wafer through the incoming ion beam.

A recent improvement for ion implanter design has been the introduction of ribbon beam technology. Here, the ions arriving at a work piece are organized into a uniform stripe that coats the work piece as it is passed beneath the stripe. The cost advantages, using ribbon been technology, are significant: For disc-type implanters, ribbon beam technology eliminates the necessity for scanning the disc across the ion beam. For single-wafer implanters the work piece need only be oscillated back and forth along a simple linear path through the incoming ribbon beam, allowing for a simple mechanical design and the elimination of expensive transverse magnetic scanning or complex two-dimensional mechanical motions.

U.S. Pat. No. 5,350,926 entitled “High current ribbon beam ion implanter” and U.S. Pat. No. 5,834,786, entitled “Compact high current broad beam ion implanter”, both issued to N. R. White et al., present some features of ribbon beam technology. White at al., have also reviewed some of the problems of generating ribbon beams in an article entitled “The Control of Uniformity in Parallel Ion Beams up to 24 inches in Size” presented on page 830 of the 1999 Conference Proceedings of “Applications of Accelerators in Research and Industry” edited by J. L. Dugan and L. Morgan published by the American Institute of Physics (1-56396-825-8/99).

The technical challenges of generating and handling ribbon beams are non-trivial. The ion species required for present-day implantation includes arsenic, phosphorus, germanium, boron and hydrogen having energies that can be adjusted to any value between 500 eV and 80 keV. In addition, the integrated ribbon beam intensities must be variable between a few microamperes and many milliamperes. Finally, the ribbon-beam ensemble must arrive at the wafer with uniformity better than 1% and with parallelism better than +/−0.5°. Reproducibly achieving these requirements on a day-to-day basis is difficult and some form of optical compensation is needed to make up for set-up errors, ion source fluctuations, vacuum pressure changes, etc.

A related invention by Kenneth H. Purser, et al. entitled “Controlling the Characteristics of Implanter Ion-Beams”, filed Jul. 17, 2003 and claiming priority of provisional patent application serial No. 60/396,332, Jul. 17, 2002, the disclosure of which is hereby incorporated by reference, describes methods and apparatus that can provide optical compensation for ribbon beam errors. However, such correction systems cannot operate without accurate information concerning the intensity and trajectory distributions of the ions within the beam and it is desirable to add a measuring system that can quickly quantify ribbon beam parameters and direct this information to an operator or an automated control interface that can make corrections by adjusting ion beam lenses and/or beam steering elements.

### SUMMARY OF THE INVENTION

While the perception of a perfect ribbon ion beam is a uniform distribution of ions traveling with identical energies, and direction of travel within a rectangular cross-sectional boundary, experience indicates that this is not always the case. In practice, angular and intensity fluctuations that originate from the ion source, alignment errors, lens aberrations and focal lengths differences from the transport optics can introduce substantial beam distortion. The effects include intensity variations across the beam and a lack of parallelism of the ions arriving at the wafer. If such errors are to be corrected using the above technology of Purser et al. it is necessary to measure intensity and angular divergences within a ribbon beam and translate this information into a manageable data set that can be used to adjust settings of the corrector elements.

The first embodiment described here essentially comprises two plane elements larger in size than the cross-section of the ribbon beam where measurements are to be made. For 300 mm wafer implementation and measurements at the wafer position, these elements need to have a width dimension of least 350 mm and a height dimension of 100 mm. At other locations along the optical path between source and wafer they may be smaller.

The first plane element consists of a plate that has been pierced by a set of modest-sized through holes or slots that define the acceptance boundaries of diagnostic beamlets that have passed unimpeded through the above holes or slots.

The diagnostic beamlets drift to the second element of the transducer, a structure of ion collection elements mounted upon a silicon wafer. These conducting collection elements are deposited on the silicon plate with precisely the same distribution pattern as that of the through holes that penetrate the first plate. Each collection element is isolated from the background silicon by an insulating layer forming one plate of a low-value capacitor to ground. Patterned around each of these capacitors are a connection grid and a circuit that shorts and opens the connections to the plates of the above capacitor when the voltage across the capacitor reaches a predetermined level. The rate at which this opening and closing of connections takes place allows a direct measurement of the incoming beamlet ion current. The reasoning for this is as follows:

Since the charge, q, on a capacitor, C, produces a voltage, V, given by

V=q/C

The average arriving current, I, is given by

I=C(dV/dt)

By employing a circuit that puts out a digital pulse every time the capacitor charges to a specific voltage one has an absolute measurement of current since

C=εA/x

where ε is the dielectric constant, x is the separation of the plates and A is the area of the parallel-plate capacitor.

During data acquisition the first plate is moved in the plane at right angles to the beam direction to produce small controlled motions with respect to the downstream silicon plate. This motion may be introduced by motors that operate independently in x and y directions or by any of the many drive mechanism known to those skilled in the art.

A circuit connected to each elemental capacitor produces a digital pulse every time the capacitor charges to a specified voltage. The analysis system acquires this signal from any selected capacitor and measures the time between successive pulses to derive the incoming beamlet current. By monitoring the motions of the first-plate it is possible to establish the relative x-y coordinates between the first-plate and the silicon plate needed to maximize an individual beamlet's current. This information, coupled with the distance between the first plate and the silicon plate, allows angular deflections to be established for each diagnostic beamlet allowing a derivation of the angle and intensity characteristics across the incoming ribbon beam.

A second embodiment for measuring ribbon-beam parameters also consists of two elements; a first-plate that is narrow in the y-direction of the ribbon beam and long in the x-direction. The first element consisting of a narrow non-magnetic plate through which is milled a group of narrow through holes or slots that define the cross section of a collection of diagnostic beamlets. The second element of the pair is a high spatial-resolution ion/secondary-electron converter that is rigidly connected to the first element but separated by a known ion-drift distance. Those skilled in the art will recognize that the length of this drift distance will be a compromise between beam-line length availability and the measurable angular resolution of the beamlets.

The rigid assembly of first-plate and ion/secondary-electron converter is moved mechanically along the long axis of the incoming ribbon beam to produce measurements of angular deviations from parallelism with the beam centerline plus the relative concentration of incoming ions across the cross-section of the ribbon beam. The above ion/secondary-electron converter produces a pattern of secondary electrons identical in shape to the patterning of the first element but is displaced in position with respect to the accepted optic axis if the incoming ions are not parallel to the beam centerline.

A suitable D.C. field accelerates the secondary electrons to a few hundred electron volts. Following this they strike the sensitive area of a charge-coupled device (CCD). Alternatively, a phosphorescent film transforms the electron energy into light. An optical transfer system demagnifies and focuses the resulting pattern onto a standard optical CCD detector which may be an ordinary digital camera. Following computer manipulation the output from either detector allows maps to be produced of the angles of incidence of the incoming ions and their relative intensity distribution across the ribbon beam.

By measuring the width of a ribbon beam, using any of the above diagnostic procedures, an accurate calculation can be derived for the wafer dose by normalization of the total ion current entering the end station to that fraction that intercepts the wafer. Electrically isolating the above first element and connecting it to a suitable meter circuit can measure the total ion current in the ribbon beam. Those skilled in the art will recognize that to achieve accuracy appropriate electron suppression is essential. While several options are available in the preferred embodiment small permanent magnets arranged in a confinement mode are located on the rear side of the first-plate.

### BRIEF DESCRIPTION OF THE DRAWINGS

For better understanding of the present invention, reference is made to the accompanying drawings:

FIG. 1 illustrates a beam coordinate system used in connection with each embodiment of the present invention;

FIG. 2 illustrates the basic transducer geometry used in connection with the embodiments;

FIG. 3 illustrates the layout of a ribbon-beam transducer used for measuring the local angles and intensities across a ribbon beam;

FIG. 4 illustrates a schematic diagram for circuit elements on a silicon plate detector;

FIG. 5 illustrates an implementation of the capacitor array on pieces of 200 mm silicon;

FIG. 6 illustrates a relaxation oscillator incorporating a unijunction transistor;

FIG. 7 illustrates the geometry used for a scanning transducer used for angle and intensity scanning across the width of a ribbon beam;

FIG. 8 illustrates the basic secondary electron production geometry used in connection with an embodiment;

FIG. 9 illustrates an apparatus used for conversion of incoming ions to electrons and subsequently to light;

FIG. 10 illustrates the geometry of an ion-electron converter with angled through holes; and

FIG. 11 illustrates the geometry of a preferred embodiment.

### DETAILED DESCRIPTION OF THE INVENTION

The unique properties of the above system according to the present invention will be better elucidated by reference to the figures listed above.

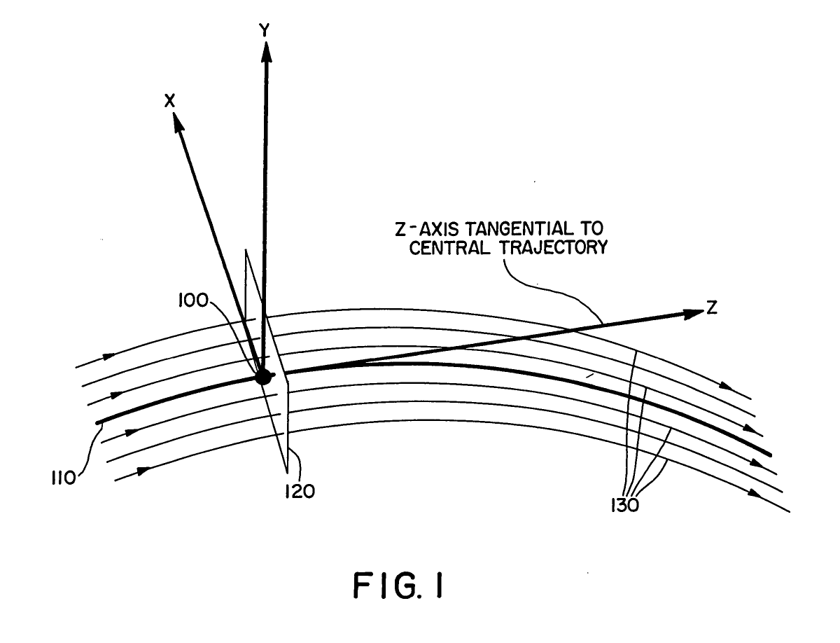

FIG. 1 illustrates the beam coordinate system used in the following discussions. The X-axis is always aligned with the surfaces, 120, at right angles to the beamlets, 130, comprising the ribbon beam and along the surface's long axis. The Z-axis, 110, is tangential to the central trajectory, of the ribbon beam and remains coincident with the central trajectory throughout the length of the ion optical transport system, causing it to change direction as the central trajectory, 110, changes direction. At each point along the beam path the Cartesian Y-axis lies also in the surface, 120, and at right angles to the ribbon beam's narrow dimension.

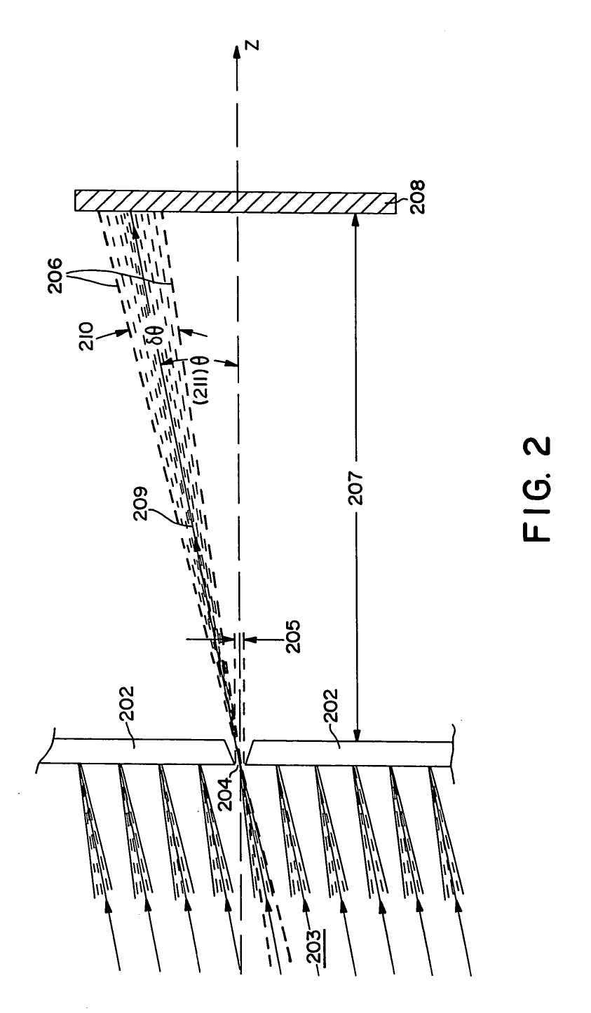

FIG. 2 shows the information available using the measuring tool described in the present patent application. The first-plate, 202, includes an array of apertures. For clarity of explanation, however, only a single circular hole is discussed here. During operation an ensemble of arriving ions, 203, impinge upon the plate, 202, which includes a small hole, 204, having diameter, 205. A small diagnostic beamlet is allowed to pass through this hole and the above beamlet, whose envelope is shown as 206, provides information about the angular width of the beam, 60, arising from angular spreads introduced by optical aberrations and the natural emittance of the ions. Also, information about the local ribbon-beam intensity distribution and the angle of the centroid trajectory, 0, with respect to the z-axis. Those skilled in the art will recognize that the dimension, 207, must be chosen in conjunction with the resolution requirements of the detector. After the above beamlet has drifted between the defining aperture, 204, and the following detection element, 208, the size of the envelope, 206, must be sufficient to measure the angular distribution with the required accuracy.

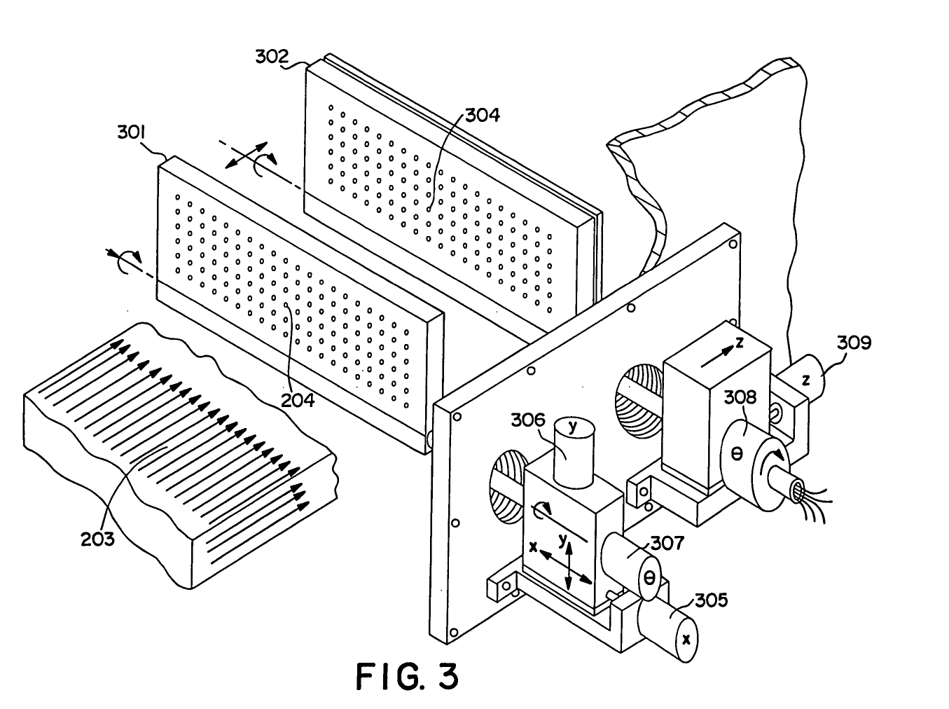

FIG. 3 shows the essential structure of a device for characterizing ribbon beams. It can be seen that the device consists of two plane elements, 301 and 302. The first of these is a perforated plate, 301, larger in size than the cross-section of the ribbon beam, 203. It is pierced by a number of through holes, 204, that define the cross sectional shape of individual diagnostic beamlets that drift through the space between the two elements, 301 and 302. For 300 mm wafer implementation, and for making beam-parameter measurements at the wafer position, the plate, 301, has a width dimension (along the x-axis) of at least 350 mm and a height dimension (along the y-axis) of at least 100 mm.

The diagnostic beamlets drift to the second element of the transducer, 302, a plate made from silicon. A pattern of conducting ion collectors, 304, is deposited onto the silicon plate, 302. The pattern has an identical distribution to the hole pattern, 204, milled through the perforated plate, 301. The individual ion collectors are isolated from the silicon plate, 302, and from the grounded enclosure by a thin film of deposited insulator causing each individual collector to become part of an elementary low-value capacitor, 401, 402. A connection grid and independent circuits are patterned around each of the elemental capacitor, causing the plates of each capacitor to be shorted to ground whenever the voltage across an individual capacitor reaches a defined value. The effect of this electrical short is to produce a significant pulse that is injected into the reading circuit, 405. Measuring the time between successive pulses using circuitry on board or external to the silicon plate, 310, allows an absolute measurement of the incoming current that arrives at an individual ion collector.

It can be seen from FIG. 3 that two independent motors, 305, 306, are used to precisely move the first element, 301, by a small controlled distance in either x or y direction. Thus, it is possible to maximize the current reaching a specific ion collector on the plate, 302, even when the beamlets do not leave the first element, 301, normally. Because the relative alignment differences between plates, 301 and 302, can be known with high precision, and because the distance between the elements 301, 302 is known, the alignment differences can be converted into emittance angles and trajectory angles for each diagnostic beamlet in the coordinates δθ, (210), and θ, (211).

Referring again to FIG. 3 it can be seen that other motions are possible. Both of the elements, 301 and 302, can be rotated out of the incoming beam using the motors 307 and 308. Also, the distance between the two elements can be adjusted by using the motor, 309, which drives the second element in the x-direction thus increasing or decreasing both the maximum detectable beam divergence angle and divergence angle sensitivity.

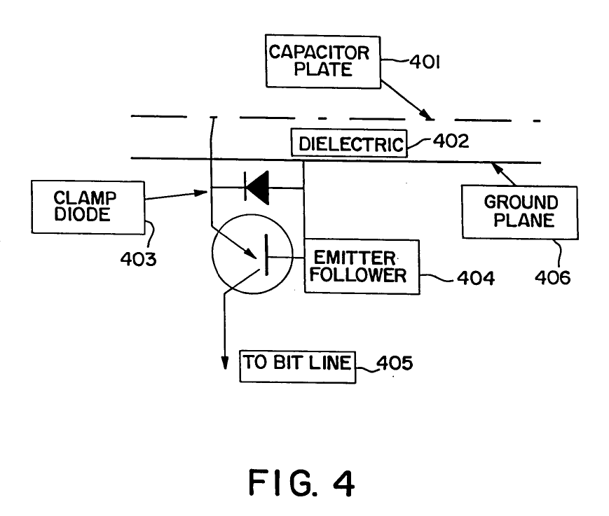

FIG. 4 shows a simple circuit that can be built into the silicon detector plate. The capacitive collector, 401, is formed above a dielectric layer, 402, one side of which is referenced to ground potential. A clamping diode, 403, across the capacitor prevents over voltage beak down from incoming charge. An emitter follower, 404, provides no voltage gain but substantially reduces the output impedance isolating the collector capacitance from the interconnecting wire capacitance. The outgoing signal travels along the bit-line 405.

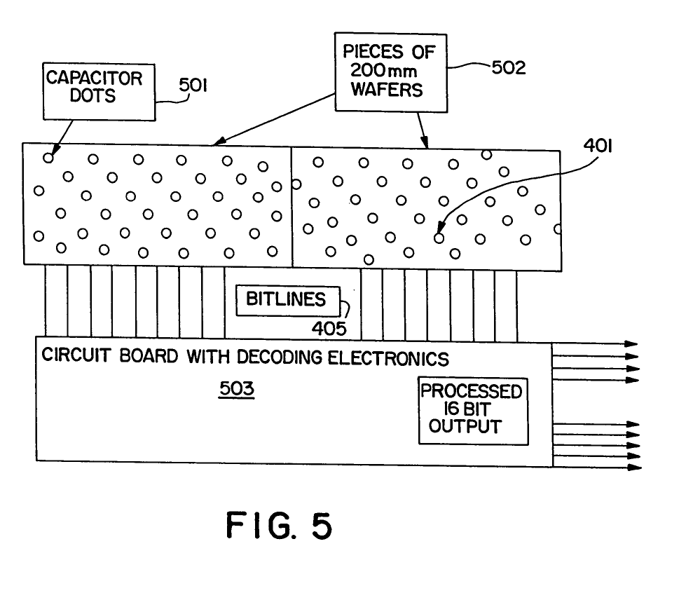

FIG. 5 shows the implementation of the capacitor array, 401, mounted upon two pieces of 200 mm silicon wafers, 502. The decoding electronics can be designed into the silicon plate, itself, or be located on an independent circuit board, 503, fastened to the back of the silicon plate. This geometry minimizes the number of wires that need be brought through the walls of the vacuum system.

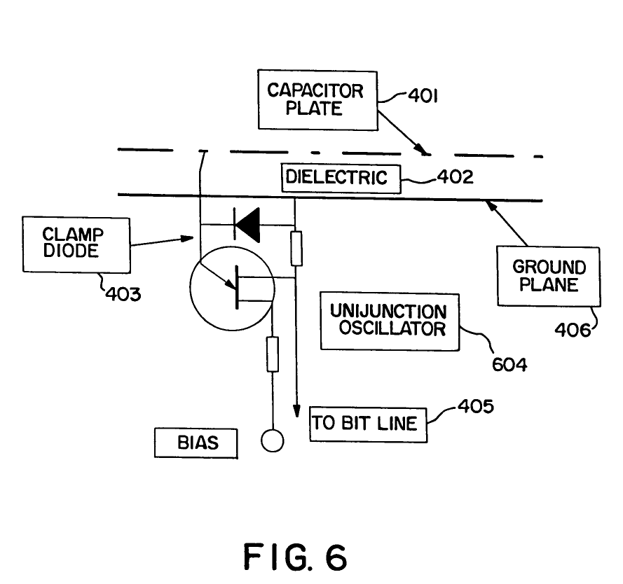

FIG. 6 shows a relaxation oscillator that includes a unijunction transistor, 404. This element discharges the capacitor, 401, at a known voltage at which time a large signal is injected onto the bit line, 405.

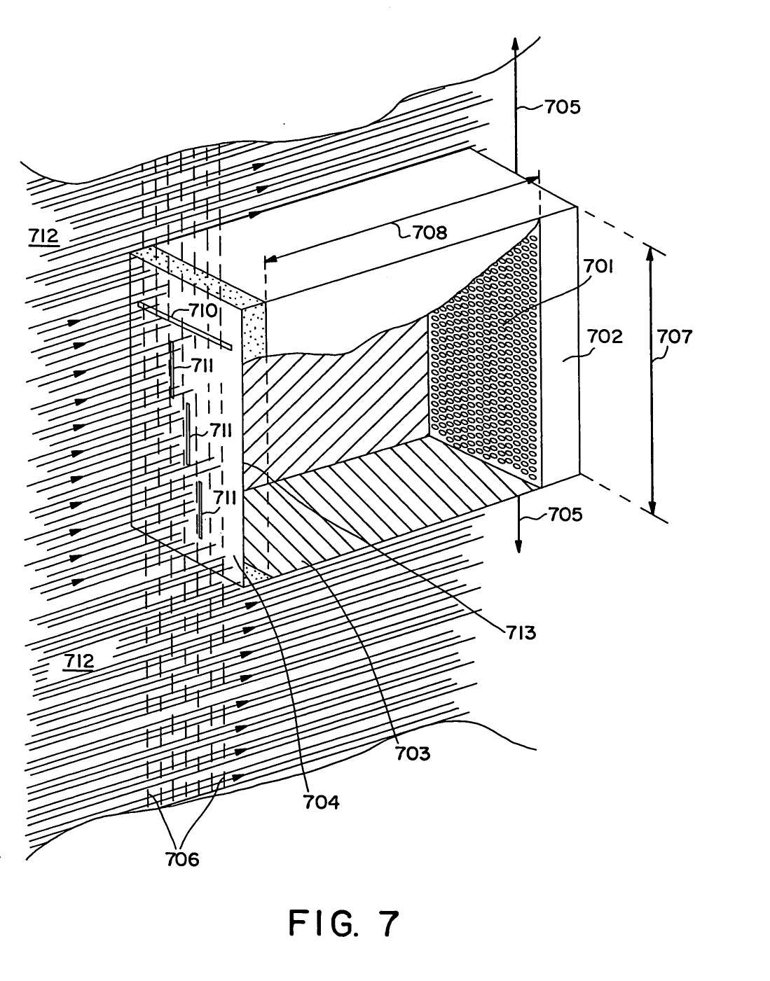

FIG. 7 shows an alternative embodiment for generating angle and intensity information across a ribbon beam. A rigid box-like structure, 703, having an insulated front surface, 704, establishes the necessary geometric constraints. During a measurement, the above box, including detection system, 701, 702, is traversed along the whole length of the incoming ribbon beam, 706 across the x-direction of the ribbon beam as shown by the arrows, 705. While it will be clear to those skilled in the art that the dimensions are not critical, in the preferred embodiment, said box-like structure has a width, 707, of 100 mm, a drift length, 708, of ˜100 mm and a height, of ˜100 mm.

Narrow slots, 710 and 711, having widths 0.25 mm allow diagnostic samples of the incoming ions, 712, to pass to the inside of the box, 703, where these diagnostic beamlets drift to the plane, 701, that defines the entrance to the detection system. As the beamlets particles drift between the defining slits, 710 and 711, and the entrance to the detection system, 701, the envelope of beamlet expands allowing angular information to be derived concerning beam emittance, the angles between individual beamlets and about intensity fluctuations across both dimensions of the ribbon beam.

While the operation of a specific converter arrangement, 701, 702, is described in the following paragraphs, those skilled in the art will recognize that there are multiple methods for converting such areal ion densities into information that can be digested by data analysis systems. Such alternative data conversion systems are inherently included in the claims of the present patent.

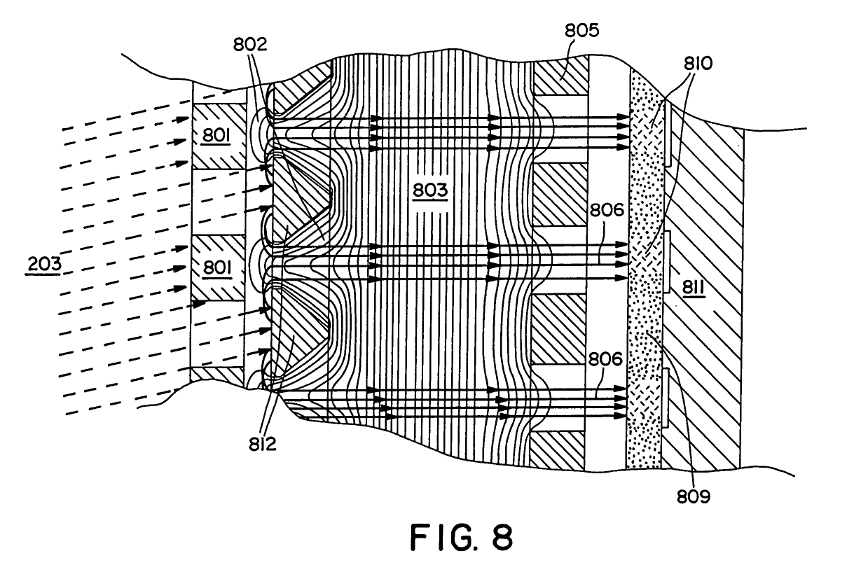

FIG. 8 illustrates how ions after reaching the detector front plate, 208 and 801, produce secondary electrons at the impact point of the secondary emission detector, 812, and how these secondary electrons are accelerated by the fringing potential fields, 802, into the acceleration region, 803. This acceleration region lies between the shadowing electrodes, 812, and the grounded electrode, 805. This region typically supports an acceleration voltage in the range 100-200 Volts. Ultimately, the fast electrons, 806, strike a phosphor film, 809, where light, 810, is produced and registered by a charge coupled device, (CCD), 811.

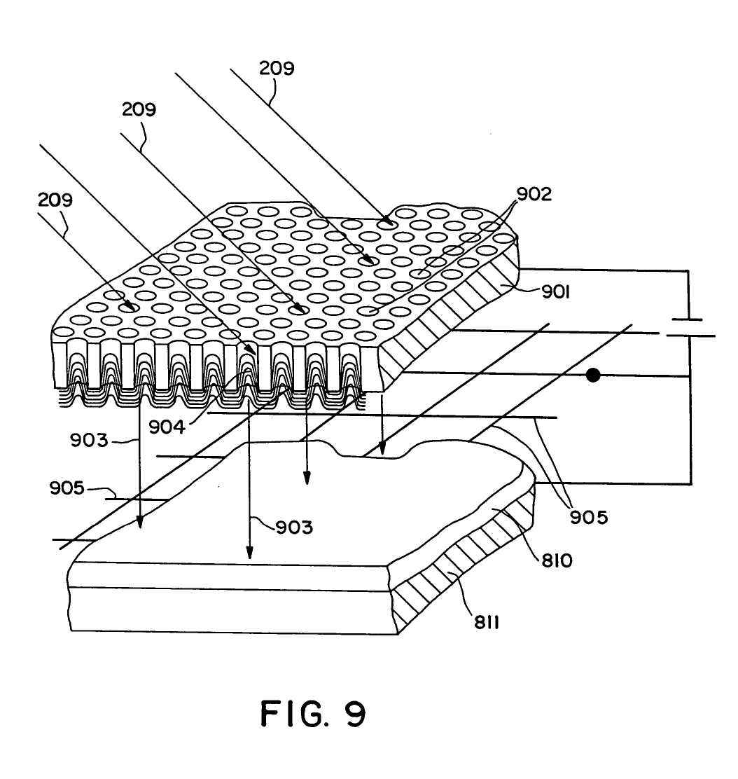

FIG. 9 shows a simplified form of the previously described incoming-ion/electron conversion device (see FIG. 8). Basically, this embodiment is a single plate, 901, manufactured from beryllium-copper, or other suitable material with a high ion/electron emission coefficient. The plate, 901, is penetrated by a large number of identical through holes, 902, arranged in a close packing pattern. Typically, the diameter of each hole is approximately one half the thickness of plate, 901. In the preferred embodiment the thickness of said plate is approximately 0.5 millimeter and the through hole diameters are approximately 0.25 millimeter. Ions, 209, that have been selected for analysis by passage through the sampling apertures or slits, 204, enter the holes, 902, at a sufficient angle to the axis of the hole that they do not penetrate the plate but rather are stopped in the wall where they produce secondary electrons, 903. Electric equi-potentials, 904, created by voltage impressed between plate, 901, and a plane acceleration grid, 905, reach into each through the hole, 902, accelerating the secondary electrons, generated at the walls of the hole, into the main accelerating region, 905, from whence they strike the phosphor film, 810, producing light that is registered by a charge-coupled device, 811.

Referring again to FIG. 9 it can be seen that the plane of said plate, 901, is not at right angles to the direction of the incident ions, 209, but rather is oriented at an angle of approximately 45°. The incoming ions do not enter individual tubes along its axis but rather strike the walls at about 45°. In some situations this geometry may be inconvenient.

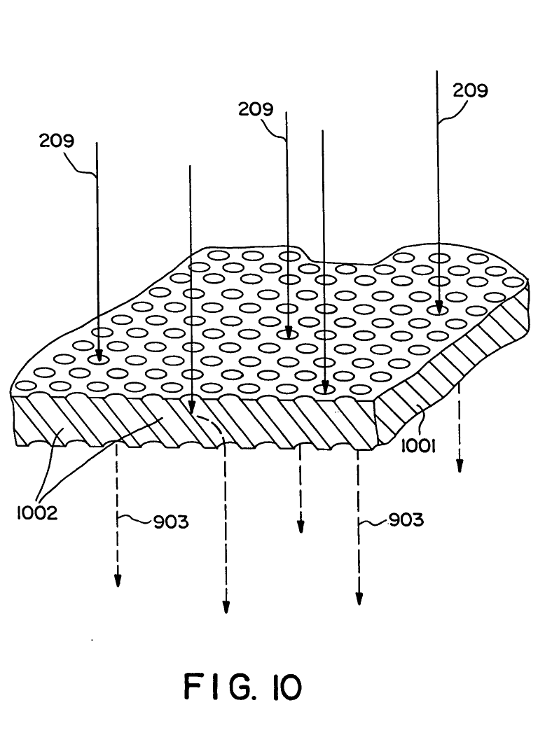

FIG. 10 shows a converter plate, 1001, which avoids the issue of 45° incidence. It operates in a similar manner to that shown in FIG. 9 as item 901. The difference is that the through holes, 1002, are themselves angled at 450 to the plate surface. Thus the plate 1001 can be oriented at right angles to the nominal direction of the incident ions.

Those skilled in the art will recognize that considerable amplification of the electron output can be achieved by using a channel-plate converter (available from Galileo Industries of Sturbridge, Mass.) in place of the converter plates described in FIGS. 9 and 10. For the anticipated beam currents used in implantation such enhancement should not be necessary. However, it may be desirable to introduce such the emittance of very low current ion beams are needed. Such enhancements to the principles of this invention are incorporated by reference.

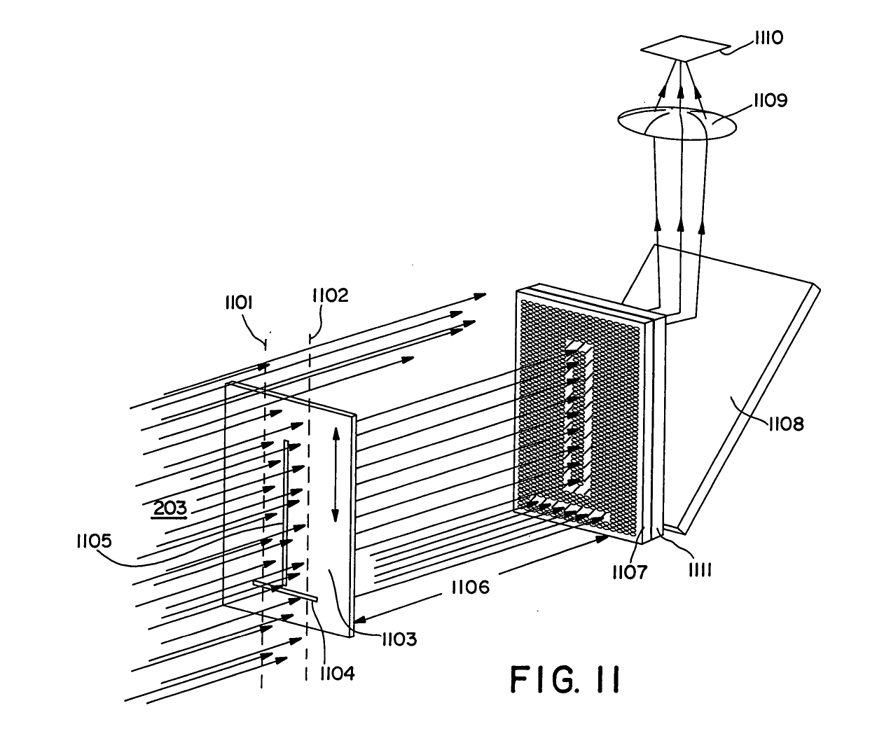

FIG. 11 shows the preferred embodiment of a version of the present invention where the ion electron converter used is of the slanted-hole variety, 1001. The incoming ribbon beam, whose height boundaries are 1101 and 1102, impinges on the front surface of plate, 1103. Diagnostic beamlets are transmitted through the narrow pair of slots at right angles, 1104 and 1105. The above diagnostic beamlets drift through the distance 1106 and impinge on the front of the particle/electron converter, 1107. Both componenets, 1103 and 1107, are connected together rigidly, and are scanned along the length of the ribbon beam to provide samples of ion parameters along both the long axis of the ribbon beam (using slot 1104) and across the width of the ribbon beam (slots 1105). Following an appropriate drift distance, 1106, the transmitted diagnostic beamlets strike an areal particle detector, 1107, whose principles have been described in FIG. 8. Angular information for both theta and phi coordinates are derived as before from the ensemble of beamlet samples. As previously described, secondary electrons are accelerated to a few hundred electron volts following which they impact a phosphor film deposited on a flat glass plate, where electron energy into photon energy that can be recognized by a standard optical CCD such as those used in modern digital cameras.

To minimize implant tool length the light pattern may be reflected into the x direction using a mirror, 1108. Following this bend the photons are focused by a short focal length lens, 1109, to produce an image size that matches the aerial extent of the two dimensional CCD detection surface area, 1110.

What is claimed is:

1. That method of making relative measurements, within a cross section of a primary ion beam consisting of a collection of a number of elementary beamlets, of the beamlets' intensity fluctuation, their emittance characteristics and their angular variations with respect to the centroid ray of said primary ion beam, which method comprises the following steps:
producing multiple elementary beamlets by impacting said ion beam on a suitably perforated mask, said beamlets being representative samples of said primary ion beam,
allowing said elementary beamlets to drift through a known distance, and thereafter,
allowing the elementary beamlets to impact a high spatial-resolution areal detector, whereby there is made possible the establishment of intensity variations between beamlets by measurement of the ion currents transported by each beamlet.

2. Method in accordance with claim 1, including the step of establishing the emittance of individual beamlets by measuring the width of said beamlet impact pattern.

3. Method in accordance with claim 1, including the step of establishing angular variations for individual beamlets with respect to the centroid trajectory of the primary ion beam.

4. Apparatus for making comparisons within the cross section of a primary ion beam of relative intensity, emittance and angular variatidns with respect to the centroid trajectory of the primary ion beam, comprising:
a perforated plate where the majority of the incoming primary ion beam is stopped;
said perforated plate including an assembly of apertures that allow diagnostic beamlets representative of local properties within the primary ion beam to pass to the down-stream side of said plate;
a high spatial resolution areal detector spaced a known distance from said perforated plate and so placed that said transmitted diagnostic beamlets drift through said known distance and impact said high spatial resolution areal detector where the areal distribution of current for each said beamlet is measured;
the magnitude of angular deflection of individual beamlets being established from the location of the pattern on the high spatial-resolution areal detector.

5 Apparatus in accordance with claim 4 where the size of said perforated mask is greater than the dimensions of said primary ion beam.

6 Apparatus in accordance with claim 4 where said apertures through said perforated plate are cylindrical holes.

7 Apparatus in accordance with claim 4 where said apertures through said perforated plate have the form of slots.

8 Apparatus in accordance with claim 4 where the array of perforations are arranged in a rectangular array.

9 Apparatus in accordance with claim 4 where the array of perforations are arranged in a close-packing array.

10 Apparatus in accordance with claim 4 where said high spatial-resolution areal detector is made from a conducting plate covered by an insulating layer onto which conductive elements are deposited across the surface of said conducting plate in the same geometry as the geometric distribution of said apertures through said perforated plate.

11 Apparatus in accordance with claim 10 where said conductor is a semiconductor.

12 Apparatus in accordance with claim 10 that allows measurement of ion currents arriving at each of the said conductive elements.

13. Apparatus in accordance with claim 4, including means for introducing relative motion between said plate and said high spatial-resolution areal detector, to permit beamlet angular deflection measurements.

14 Apparatus in accordance with claim 4 where the size of said perforated mask and high spatial-resolution areal detector is considerably smaller than that of said primary ion beam.

15 Apparatus in accordance with claim 14 where said perforated mask and high spatial-resolution areal detector are rigidly connected together and the assembly is scanned mechanically across the width of said primary ion beam.

16 Apparatus in accordance with claim 4 where the high spatial-resolution areal detector is a broad area secondary electron producer that directs said secondary electrons onto a suitable electron detector.

17 Apparatus in accordance with claim 16 where the said electron detector is a phosphorescent screen.
